(19) United States
(12) Patent Application Publication
(10) Pub. No.: US 2015/0087156 A1
(43) Pub. Date: Mar. 26, 2015

(54) ETCHING METHOD, AND METHOD OF PRODUCING SEMICONDUCTOR SUBSTRATE PRODUCT AND SEMICONDUCTOR DEVICE USING THE SAME, AS WELL AS KIT FOR PREPARATION OF ETCHING LIQUID

(71) Applicant: FUJIFILM Corporation, Tokyo (JP)

(72) Inventors: Tetsuya KAMIMURA, Haibara-gun (JP); Tadashi INABA, Haibara-gun (JP); Naotsugu MURO, Haibara-gun (JP); Yoshinori NISHIWAKI, Haibara-gun (JP)

(73) Assignee: FUJIFILM Corporation, Tokyo (JP)

(21) Appl. No.: 14/558,838

(22) Filed: Dec. 3, 2014

Related U.S. Application Data
(63) Continuation of application No. PCT/JP2013/069960, filed on Jul. 17, 2013.

(30) Foreign Application Priority Data
Jul. 20, 2012 (JP) 2012-161905

(51) Int. Cl. H01L 21/306; C09K 13/00

(52) U.S. Cl. CPC H01L 21/30604; C09K 13/00
USPC 438/704; 252/79.1

(57) ABSTRACT

A method of etching a semiconductor substrate, having the steps of: preparing an etching liquid by mixing a first liquid with a second liquid to be in the range of pH from 8.5 to 14, the first liquid containing a basic compound, the second liquid containing an oxidizing agent; and then applying the etching liquid to a semiconductor substrate on a timely basis for etching a Ti-containing layer in or on the semiconductor substrate.

### CROSS-REFERENCE TO RELATED APPLICATIONS

This application is a Continuation of PCT International Application No. PCT/JP2013/069960 filed on Jul. 17, 2013, which claims priority under 35 U.S.C. §119 (a) to Japanese Patent Application No. 2012-161905 filed on Jul. 20, 2012. Each of the above applications is hereby expressly incorporated by reference, in its entirety, into the present application.

### TECHNICAL FIELD

The present invention relates to a method of etching a semiconductor substrate, and a method of producing a semiconductor substrate product and a semiconductor device using the same, as well as a kit for preparation of an etching liquid.

### BACKGROUND ART

The miniaturization and diversification of semiconductor devices has progressed more and more, and a processing method thereof covers a wide range with respect to each of device structures and production steps. With regard to etching of a substrate, for example, a variety of chemical species, processing conditions and the like has been proposed in accordance with kinds and structures of the substrate material in both a dry etching and a wet etching, and further intensive research and development is in progress.

In particular, when a device structure of CMOS, DRAM, and the like is produced, the technique of precisely etching a prescribed material is important, and as an example thereof, a wet etching which uses a chemical liquid is exemplified. For example, a precise etching processing is required in the production of circuit wiring of a microscopic transistor circuit, a metal electrode material, or a substrate having a barrier layer, a hard mask, and the like. However, etching conditions and chemical liquids, which are applied to a substrate having a variety of metal compounds, have not yet been studied sufficiently.

There are examples of studies on chemical liquids which selectively etch a TiN layer that constitutes a device substrate. For example, Patent Literature 1 proposes an etching liquid containing a specific amount of hydrogen peroxide and tetraalkyl ammonium, the pH of the etching liquid at 25 degrees C. being from 6.0 to 8.2, and an etching method using the same.

### CITATION LIST

### Patent Literature

Patent Literature 1: JP-A-2010-10273 (“JP-A” means unexamined published Japanese patent application)

### DISCLOSURE OF INVENTION

### Technical Problem

The inventors have investigated a chemical liquid that enables etching of a layer containing Ti (hereinafter, may be referred to as “Ti-containing layer”), and an etching method using the same. The inventors have thus proceeded with their studies on the newly-developed etching liquid described above, and then found that probably due to the influence of the high pH of the etching liquid, deactivation with age, which is seen as being caused by decomposition of active components, becomes conspicuous.

The present invention has been made in view of the above, and addresses to the provision of a method of etching a semiconductor substrate, the method improving activity of an etching liquid for lasting against age and realizing good wet etching performance of the Ti-containing layer. Further, the present invention addresses to the provision of a method of producing a semiconductor substrate product, being provided with the above improvement and performance, and a semiconductor device using the same, as well as a kit for preparation of an etching liquid.

### Solution to Problem

According to the present invention, there is provided the following means:

[1] A method of etching a semiconductor substrate, having the steps of:

preparing an etching liquid by mixing a first liquid with a second liquid to be in the range of pH from 8.5 to 14, the first liquid containing a basic compound, the second liquid containing an oxidizing agent; and then

applying the etching liquid to a semiconductor substrate on a timely basis for etching a Ti-containing layer in or on the semiconductor substrate.

[2] The etching method according to item [1],

wherein the first liquid and the second liquid are, respectively, put into flow channels different from each other, the both liquids are then joined at the injunction portion of the flow channels to mix them, and the etching liquid prepared by the mixing is applied to the semiconductor substrate.

[3] The etching method according to item [1] or [2],

wherein the first liquid is an aqueous composition of the basic compound having a concentration from 0.1 to 10% by mass and the second liquid is an aqueous composition of the oxidizing agent having a concentration from 1 to 40% by mass.

[4] The etching method according to any one of items [1] to [3],

wherein the etching liquid is prepared so that the concentration of the basic compound in the etching liquid is from 0.05 to 10% by mass.

[5] The etching method according to any one of items [1] to [4],

wherein the etching liquid is prepared so that the concentration of the oxidizing agent in the etching liquid is from 0.5 to 10% by mass.

[6] The etching method according to any one of items [1] to [5],

wherein the etching liquid is applied to a surface of a rotating semiconductor substrate.

[7] The etching method according to any one of items [1] to [6],

wherein the etching liquid is provided from a discharge opening, and

wherein the application of the etching liquid is performed while moving the discharge opening along with a locus headed in the direction from a central portion of the semiconductor substrate to the edge thereof with respect to the surface of the rotating semiconductor substrate.

[8] The etching method according to any one of items [1] to [7],

wherein the basic compound is a compound represented by formula (I):

N(R)₄OH Formula (I)

wherein R represents a substituent; and a plurality of Rs may be the same or different from each other.

[9] The etching method according to any one of items [1] to [8],

wherein the basic compound is tetramethylammonium hydroxide, tetraethylammonium hydroxide, or tetrapropylammonium hydroxide.

[10] The etching method according to any one of items [1] to [9],

wherein the oxidizing agent is hydrogen peroxide, ammonium persulfate, perboric acid, peracetic acid, periodic acid, perchloric acid, or a combination thereof

[11] The etching method according to any one of items [1] to [10],

wherein the temperature, at which the etching liquid is brought into contact with the semiconductor substrate and etches the same, is 40° C. or more.

[12] The etching method according to any one of items [1] to [11],

wherein the semiconductor substrate comprises:

a Ti-containing layer as a first layer; and

a second layer containing at least one of Cu, SiO, SiN, SiOC, and SiON,

wherein the first layer is selectively etched with respect to the second layer by the etching.

[13] The etching method according item [12], wherein the first layer is laminated on or above the second layer.
[14] The etching method according to item [12] or [13], wherein an etching rate ratio of an etching rate (R1) of the first layer to an etching rate (R2) of the second layer (R1/R2) is 30 or more.
[15] The etching method according to any one of items [12] to [14], wherein the etching is conducted after the second layer is processed by a dry etching process.
[16] The etching method according to any one of items [1] to [15], wherein the etching liquid comprises a water-soluble organic solvent.
[17] The etching method according to item [16], wherein the water-soluble organic solvent is an alcohol compound or an ether compound.
[18] The etching method according to item [16] or [17], wherein the concentration of the water-soluble organic solvent is set at 1 to 50 mass %, with respect to the etching liquid.
[19] The etching method according to any one of items [1] to [18], comprising a step of washing with water a substrate surface after etching.
[20] A method of producing a semiconductor substrate product, producing the semiconductor substrate product using a semiconductor substrate processed by the etching method according to any one of items [1] to [19].
[21] A method of producing a semiconductor device, producing the semiconductor device using the semiconductor substrate product obtained by the production method according to item [20].
[22] A kit for preparation of an etching liquid, comprising:

a first liquid and a second liquid in combination, the first liquid containing a basic compound, the second liquid containing an oxidizing agent,

wherein the etching liquid can be prepared by mixing at least the first liquid with the second liquid, and the etching liquid is on a timely basis to be applied to a semiconductor substrate for etching a Ti-containing layer provided in or on the substrate.

In the present specification, the term “having” is to be construed in the open-ended meaning as well as the term “comprising” or “containing.” Further, the term “preparing” is to be construed in the broadest manner as the meaning of making materials ready to be used, e.g., not only the meaning of producing or synthesizing the materials, but also purchasing them.

### Advantageous Effects of Invention

According to the method and kit of the present invention, activity of an etching liquid can be improved for the activity lasting against age, and good wet etching performance of the Ti-containing layer can be attained. Specifically, high etching rate and selectivity with respect to the Ti-containing layer can be realized and further generation of etching unevenness and defects can favorably be suppressed.

Other and further features and advantages of the invention will appear more fully from the following description, appropriately referring to the accompanying drawing.

### BRIEF DESCRIPTION OF THE DRAWINGS

FIG. 1 is an example of a flow chart showing a part of preferable etching steps according to the present invention.

FIG. 2 is an example of an equipment configuration diagram showing a part of wet etching equipment according to a preferable embodiment of the present invention.

FIG. 3 is an example of a plan view diagrammatically showing a movement locus of a nozzle with respect to a semiconductor substrate according to one embodiment of the present invention.

FIG. 4 is a section view diagrammatically showing an example of a production step of a semiconductor substrate (before etching) according to one embodiment of the present invention.

FIG. 5 is a section view diagrammatically showing an example of a production step of a semiconductor substrate (after etching) according to one embodiment of the present invention.

### MODE FOR CARRYING OUT THE INVENTION

The etching method of the present invention includes: mixing a first liquid containing a basic compound with a second liquid containing an oxidizing agent to prepare an etching liquid; and after the mixing, applying the etching liquid onto a semiconductor substrate on a timely basis. When shown together with steps before and after production of a semiconductor substrate product, a preferable embodiment of the present invention is as shown in the flow chart of FIG. 1. That is, in Step I, at first, dry etching is subjected to a part of the Ti-containing layer which is a first layer or a layer containing Cu, SiO, SiN, SiOC or SiON which becomes a second layer. Next, in Step II, Liquid A and Liquid B each of which serves as a raw material are mixed. After that, an etching liquid thus obtained by mixing them is applied onto a semiconductor substrate on a timely basis after preparation of the etching liquid, thereby etching a layer containing Ti that becomes a first layer (Step III). Further, after that, a substrate surface after processing is washed with water, thereby performing a post treatment (Step IV). This flow chart indicates, as a deformation example of the above embodiment, an embodiment in which an oxidizing agent that functions as a component of the chemical liquid is appropriately supplemented before a post-treatment, thereby processing again another substrate (Step V). Each of the above steps is described below. In consideration of relation to the nature of the present invention, Step II and Step III are described in this order, and then other steps are described in series.

### [Step II]

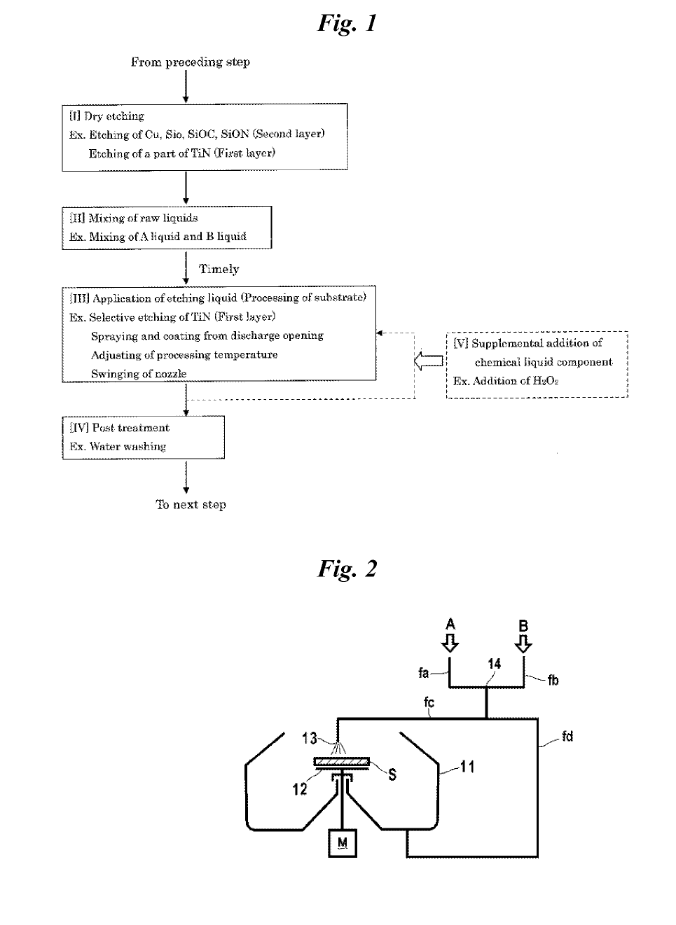

In Step II in the present invention, a first liquid containing a basic compound and a second liquid containing an oxidizing agent are mixed to prepare an etching liquid. After that, the etching liquid is provided for processing of a semiconductor substrate on a timely basis (see Step III described below). In the processing ranging from the Step II to Step III, either single wafer type equipment or immersion equipment may be used. In the embodiment shown in FIG. 2, the view shows that a Ti-containing layer of the semiconductor substrate is etched using single wafer type cleaning equipment (only a part thereof is shown on the drawing).

A in FIG. 2 indicates Liquid A that is a raw material of the etching liquid and the Liquid A is also referred to as a first liquid containing a basic compound described below. B indicates Liquid B that is a raw material of the etching liquid and the Liquid B is also referred to as a second liquid containing an oxidizing agent described below. The Liquid A (first liquid) fed to Flow channel fa toward the circulation direction A joins the Liquid B (second liquid) passed through another Flow channel fb at Injunction point 14. At this moment, the Liquid A (first liquid) and the Liquid B (second liquid) are mixed at the Injunction point 14 whereby an etching liquid is prepared. The etching liquid further passes through Flow channel fc and reaches Discharge opening 13 installed in Processing room (tank) 11. The Discharge opening 13 may have any form and, for example, a nozzle of the type of applying an etching liquid by spraying, a nozzle of the type of applying an etching liquid by dropping, a nozzle of the type of applying an etching liquid by falling, or the like can be suitably used. Especially, the spray nozzle is preferable from the viewpoint of uniform etching on a substrate surface. In the embodiment shown in FIG. 2, the spray nozzle is diagrammatically shown and the situation in which the etching liquid spreads in mist and reaches Substrate S is described. At this moment, Semiconductor substrate S is rotated by Driving means (motor) M, whereby a misty etching liquid is received uniformly over the entire substrate surface.

### Explanation of First Liquid

The first liquid in the present invention means a liquid composition containing a basic compound and may contain arbitrary components described below. It is preferable for the first liquid to contain the basic compound and a water-soluble organic solvent in water medium. The concentration of the basic compound is such that a favorable concentration is obtained when the etching liquid described below is prepared, and the concentration of the basic compound is preferably equal to or greater than 0.1% by mass, and more preferably equal to or greater than 0.5% by mass. The upper limit is preferably equal to or less than 10% by mass, and more preferably equal to or less than 5% by mass. The setting of the concentration of the basic compound within the above described range in the first liquid is preferable because when an etching liquid is prepared, the setting of the concentration makes it easy to formulate a composition that suppresses an excess etching processing of a second layer.

The concentration in the case of adding a water-soluble organic solvent, although it is not particularly limited, is preferably equal to or greater than 1% by mass, and more preferably equal to or greater than 5% by mass. The upper limit is preferably equal to or less than 80% by mass, and more preferably equal to or less than 50% by mass. The setting of the concentration of the basic compound within the above described range in the first liquid is preferable because when an etching liquid is prepared, the setting of the concentration makes it easy to formulate a composition that suppresses an excess etching processing of the second layer.

### Explanation of Second Liquid

The second liquid in the present invention means a liquid composition containing an oxidizing agent and may contain arbitrary components described below. It is preferable for the second liquid to contain an oxidizing agent in a water medium. The concentration of the oxidizing agent is such that a favorable concentration is obtained when the etching liquid described below is prepared, and the concentration of the oxidizing agent is preferably equal to or greater than 15% by mass, and more preferably equal to or greater than 25% by mass. The upper limit is preferably equal to or less than 45% by mass, and more preferably equal to or less than 35% by mass. By setting the concentration of the oxidizing agent within the above described range in the second liquid, when an etching liquid is prepared, it is easy and preferable to formulate a composition by which a Ti-containing layer is processed at high speed.

The mixing ratio of the first liquid and the second liquid, although it is not particularly limited, is preferably from 0.1:1 to 1:0.05, more preferably from 0.5:1 to 1:0.1, and particularly preferably from 1:1 to 1:0.2, when indicated in terms of the ratio of the first liquid:the second liquid.

The length and the size of the flow channel are not particularly limited. However, it is preferable that the length of Flow channel fc after interflow is set such that the time the liquid takes to reach Discharge opening 13 from Injunction point 14 is “on a timely basis (timely)” described above. In other words, it is preferable to set an arrival time of an etching liquid to a substrate under the conditions that activities of the etching liquid are not excessively reduced.

In immersion equipment, a configuration without the use of a flow channel may be available. An alternative configuration may be such that a plurality of liquids is joined together while letting them flow in the same manner as mentioned above and the thus-mixed and prepared etching liquid is fed to a reaction tank. At this time, it is also preferable that after the preparation of the liquid by mixing, the etching liquid is fed to the reaction tank “on a timely basis”.

In the above embodiment, the examples in which two liquids are mixed are described. However, the above embodiment is not limited to this type, and may be an embodiment in which three or more raw material liquids are mixed at the same time or in series. For example, a third liquid in which the above-described water-soluble organic solvent is contained in a water medium is prepared and the third liquid may be mixed with a first liquid containing a basic compound and a second liquid containing an oxidizing agent.

### [Step III]

The Step III in the present invention is a step of applying the etching liquid obtained by the Step II onto a semiconductor substrate “on a timely basis” after the preparation of an etching liquid, thereby etching a layer containing Ti that becomes a first layer. Herein, the terms “on a timely basis (timely)” after mixing defines the meaning of a period of time prior to a desired function being lost after mixing. Specifically, the period of time is preferably within 60 minutes, more preferably within 30 minutes, and particularly preferably within 10 minutes. The lower limit of the period of time is not particularly limited. However, application onto the semiconductor substrate after an interval of at least one second from termination of mixing is practical. The Step III is described again using FIG. 2. The etching liquid prepared in the Step II is sprayed from Discharge opening 13 and applied onto the upper surface of Semiconductor substrate S. Further, it is preferable that the Semiconductor substrate S is placed on Rotary table 12, and rotated with the rotary table by means of Rotary drive member M.

### Condition of Etching

In the present embodiment, the conditions for etching are not particularly limited. For example, either single wafer type (spray-type, drop-type, falling-type, or the like) etching as shown diagrammatically, or immersion type (batch type) etching may be applicable. In particular, single wafer type etching is preferable. In single wafer type etching, it is preferable to transport or rotate a semiconductor substrate in the prescribed direction and to spray an etching liquid into the space, thereby bringing the etching liquid into contact with the semiconductor substrate. On the other hand, in the batch-type etching, a semiconductor substrate is immersed in a liquid bath constituted of an etching liquid, thereby bringing the etching liquid into contact with the semiconductor substrate in the liquid bath. These etching processes may be appropriately used depending on the structure, the material, and the like of a device. Further, the etching liquid is a liquid which has been prepared by mixing in the above Step II, and a liquid in which a basic compound and an oxidizing agent are contained in a water medium is used. Details of component composition thereof are described after description of each step.

The processing temperature at which etching is conducted in the single wafer type is preferably equal to or greater than 40° C., more preferably equal to or greater than 50° C., and particularly preferably equal to or greater than 60° C. The upper limit is preferably equal to or less than 90° C., and more preferably equal to or less than 80° C. At this moment, the measurement position of the heating temperature may be appropriately determined in a relation to line structure and wafer, and typically may be controlled according to a temperature of the above-described tank (processing room) and a temperature of the feeding liquid. In the case where severe conditions are required according to performances, if both measurement and control are possible, it may be defined by a surface temperature of the wafer as in Examples described below. By controlling the temperature to the above-described lower limit or greater, a sufficient etching rate with respect to the Ti-containing layer can be preferably secured. By controlling the temperature to the above-described upper limit or lower, the stability of the chemical liquid can be preferably secured.

The feeding rate of the etching liquid, although it is not particularly limited, is preferably set within the range from 0.1 to 3.0 L/min and more preferably from 0.3 to 2.0 L/min. By controlling the feeding rate to the above-described lower limit or greater, in-plane uniformity of etching can be preferably secured at more excellent level. By controlling the temperature to the above-described upper limit or lower, stable selectivity at the time of continuous processing can be preferably secured. When a semiconductor substrate is rotated, it is preferable to rotate the semiconductor substrate at the range from 50 to 400 rpm from the same viewpoint as the above, although it may vary depending on the size or the like of the semiconductor substrate.

In the case of the batch type, it is also preferable to control the liquid bath to the above-described temperature range from the same reason as the above. The immersing time of the semiconductor substrate, although it is not particularly limited, is preferably set so as to be from 0.5 to 30 minutes and more preferably from 1 to 10 minutes.

### Swing Speed

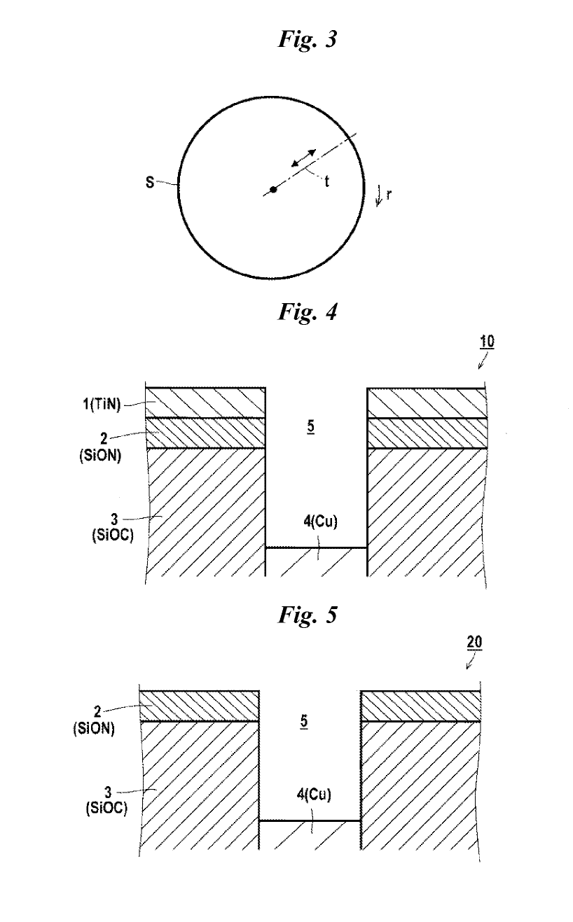

In the single wafer type etching equipment configuration according to a preferable embodiment of the present invention, it is preferable to apply an etching liquid while moving a discharge opening (nozzle), as shown in FIG. 3. Specifically, in the present embodiment, when an etching liquid is applied onto Semiconductor substrate S having a Ti-containing layer, the substrate is rotated in the r direction. On the other hand, the discharge opening is moved along with Movement locus t extending from a central portion of the semiconductor substrate to the edge thereof. Thus, in the present embodiment, the rotation direction of the substrate and the moving direction of the discharge opening are set so as to be a different direction from one another whereby they are subjected to a relative movement with respect to one another. As a result, the configuration is such that an etching liquid can be evenly applied onto the entire surface of the semiconductor substrate whereby the uniformity of etching is favorably secured.

The moving rate of the discharge opening (nozzle), although it is not particularly limited, is preferably equal to or greater than 0.1 cm/s, more preferably equal to or greater than 1 cm/s. On the other hand, the upper limit is preferably equal to or less than 30 cm/s, more preferably equal to or less than 15 cm/s. The movement locus may be a straight line or a curve (for example, arc-like). In each case, the moving rate can be calculated from an actual length of the locus and the time it takes for movement.

### Explanation of Etching State

FIG. 4 is a view showing a semiconductor substrate before etching. In the production example of the present embodiment, a layered product is used, in which SiOC layer 3 and SiON layer 2 as a second layer are disposed on a silicon wafer (not shown) and TiN layer 1 is formed on the second layer. At this moment, Via 5 has been already formed in the above-described composite layer, and Cu layer 4 has been formed at the bottom of the Via 5. Onto Substrate 10 at this state, an etching liquid (not shown) according to the present embodiment is applied to remove the TiN layer. The above-described etching liquid has removability and washability of a residue that is produced by plasma etching, ashing, and the like whereby the residue (not shown) also can be effectively removed. As a result, Substrate 20 having a configuration in which the TiN layer has been removed as shown in FIG. 5 can be obtained. Needless to say, although the etching and washing state as graphically shown is ideal to the present invention, a remainder of the TiN layer or the residue or alternatively some corrosion of the second layer is appropriately acceptable according to a required quality of a semiconductor device to be produced and, therefore, the present invention is not construed to a limited extent by the above description.

Note that the term “silicon substrate” or “semiconductor substrate” is used in the sense of including not only a silicon wafer, but also a whole extent of the substrate structure having thereon a circuit structure. The term “the element of the substrate” refers to an element that constitutes the silicon substrate that is defined above, and may be made of a single material or a plurality of materials. A processed semiconductor substrate is sometimes called as a semiconductor substrate product by a distinction. A tip or a processed product thereof, which has been obtained by further processing the semiconductor substrate, if needed, and then by singulating the same is referred to as semiconductor device or semiconductor equipment. With respect to the direction of the semiconductor, in reference to FIG. 4, the opposite side to the silicon wafer (TiN side) is called as “upper”, or “head edge”, while the silicon wafer side (SiOC side) is called as “under”, or “bottom”.

### [Step I]

In the Step I of the present embodiment, a layer containing Cu, SiO, SiN, SiOC or SiON (second layer) is subjected to dry etching. By this processing, a layer structure necessary in a semiconductor substrate is formed. As for the dry etching, a method that is ordinarily applied to this kind of products can be used. As a representative method, for example, “Semiconductor Dry Etching Technique” (Integrated Circuit Process Technique Series, authored by Tokuyama) or the like can be referred to. In a preferable embodiment of the present invention, an etching liquid or an etching method which exhibits a good removability of the residue can be provided. Accordingly, even if a residue derived from dry etching of a second layer is generated in the above-described Step 1, the etching liquid or the etching method according to the present invention is preferable because of good removability of the residue.

### [Step IV]

In the present step, the substrate surface after the above-described etching (Step III) is washed with water whereby a post treatment is performed. By this treatment, components of the etching liquid applied at the time of etching are removed whereby generation of defects on the substrate surface can be prevented. The washing method is not particularly limited, and a method that is ordinarily applied to this kind of products can be used. As a representative method, for example, “Semiconductor Cleaning Technique For Beginner” (Beginners Books, co-authored by Yasuhiro Horiike and Hiroteru Ogawa, Kogyo Chosakai) or the like can be referred to. Water which is applied at this moment is preferably ultrapure water. In the present cleaning step, it is preferable that the cleaning conditions are appropriately set. Examples of the conditions to be controlled include a rinse time of water (for example, from 10 to 60 seconds), a flow rate of water (for example, from 20 ml/min to 200 ml/min) and a throwing method of water (for example, spray-type).

### [Step V]

The present step shows, as a deformation example, an embodiment of appropriately replenishing an oxidizing agent which becomes a chemical liquid component before a post treatment, thereby again performing the processing of the substrate. The replenishing component is preferably an oxidizing agent. By this replenishment, an oxidizing agent such as hydrogen peroxide that has been broken down is replenished whereby a sufficient amount of the oxidizing agent can be maintained in the system. The replenishing amount may be appropriately set according to an amount and kind of the Ti-containing layer to be processed, or a decomposition amount of the oxidizing agent. Stated as a representative example, a replenishing amount to be applied is preferably in an amount from 1/1 to 1/10 (mass standard) of the oxidizing agent in the etching liquid used in the first processing. The replenishing method at this moment is not particularly limited. Given explanation of equipment shown in FIG. 2 as an example, examples of the replenishing form include a configuration in which a recovery opening for the etching liquid after processing is provided at the bottom of Processing room 11 and the etching liquid recovered through Bypass flow channel fd from there is fed again as the Liquid B, while replenishing an oxidizing agent to the recovered etching liquid as needed.

In the present invention, the etching liquid can be re-used in circles as described above. A preferable method is not a manner to keep a liquid running with evacuation (not re-used), but a method of re-using it in cycles. Circulation can be conducted for at least 1 hour after heating whereby a repetitive etching can be achieved. The upper limit of the time period for cyclic reheating is not particularly limited. However, exchange within 1 week is preferable because etching rate deteriorates. The exchange within 3 days is more preferable, and each day replacement with a fresh liquid is particularly preferable. Further, since an alkaline chemical liquid has a property of absorbing carbon dioxide, use in a hermetically-sealed system to the greatest possible extent, or alternatively use while flowing nitrogen is preferable, and the nitrogen flow is more preferable.

### [Etching Liquid]

The etching liquid of the present embodiment contains an oxidizing agent and a basic compound, and these materials are preferably contained in a water medium. Hereinafter, each of components including optional components is described.

### (Oxidizing Agent)

Examples of the oxidizing agent include hydrogen peroxide, ammonium persulfate, perboric acid, peracetic acid, periodic acid, perchloric acid, or a combination thereof. Among them, hydrogen peroxide is particularly preferable.

It is preferable for the oxidizing agent to be contained in a range of at least 0.5% by mass, more preferably in a range of at least 1% by mass, and still more preferably in a range of at least 2% by mass, with respect to the total amount of the etching liquid of the present embodiment. On the other hand, the upper limit thereof is preferably equal to or less than 20% by mass, and more preferably equal to or less than 15% by mass, and particularly preferably equal to or less than 10% by mass. By setting the content to the above-described upper limit or less, excessive etching of the second layer can be preferably suppressed more efficiently. It is preferable to set the content to the above-described lower limit or greater from the viewpoint of speed enough for etching the first layer.

### (Basic Compound)

The basic compound, although it is not particularly limited as long as it has alkalinity, is preferably an organic basic compound and more preferably an organic amine compound (ammonium compounds are included therein). As the organic amine compound, a compound in which a structure of a primary to tertiary amine or a quaternary ammonium is incorporated is more preferable. Examples of the compound include a primary alkylamine having 1 to 6 carbon atoms which may have substitute T below, a primary aromatic amine having 6 to 12 carbon atoms which may have substitute T below, a secondary amine having 2 to 6 carbon atoms which may have substitute T below (in case of including an aromatic group, the carbon number may be preferable in 7 to 24), a tertiary amine having 3 to 6 carbon atoms which may have substitute T below (in case of including an aromatic group, the carbon number may be preferable in 8 to 24), a quaternary ammonium having 4 to 16 carbon atoms or a salt thereof which may have substitute T below. Further, aminoalchol (preferably having carbon atoms 1 to 12, including 2-aminoethanol) and guanidine carbonate can be exemplified.

The above primary amines, secondary amines, and tertiary amines may respectively preferably be represented in following formulae (A-1) to (A-3). R defines the meaning same as that defined in Formula (I).

NRH₂ Formula (A-1)

NR₂H Formula (A-2)

NR₃ Formula (A-3)

Especially, a basic compound represented by the following Formula (I) is preferable.

N(R)₄OH Formula (I)

R represents a substituent. A plurality of Rs may be the same or different from each other. Examples of R include an alkyl group (a straight alkyl group, a cyclic alkyl group, an aralkyl group or the like are included therein), an alkenyl group, an alkynyl group, and a group having an aryl group. Especially, it is preferable for R to be an alkyl group, an alkenyl group, an alkynyl group, or an aryl group. It is more preferable for R to be an alkyl group having 1 to 8 carbon atom(s), an alkenyl group having 2 to 8 carbon atom(s), an alkynyl group having 2 to 8 carbon atom(s), or an aryl group having 6 to 20 carbon atoms (preferably 8 to 20). Herein, the above alkyl group, alkenyl group, alkynyl group, or aryl group may have a substitute T which includes a hydroxyl group, an amino group, a carboxyl group, or a halogen atom (chlorine, fluorine, bromine or the like).

Among the compounds represented by formula (I), tetramethylammonium hydroxide (TMAH), tetraethylammonium hydroxide (TEAH) tetrapropylammonium hydroxide (TPAH), and tetrabuhylammonium hydroxide (TBAH) are preferable.

These compounds may be used in combination thereof.

It is preferable for the basic compound to be contained in a range of at least 0.05% by mass and more preferably in a range of at least 0.5% by mass, with respect to the total amount of the etching liquid of the present embodiment. The upper limit thereof is preferably equal to or less than 30% by mass, more preferably equal to or less than 10% by mass, still more preferably equal to or less than 5% by mass, and particularly preferably equal to or less than 3% by mass. Setting the content of the basic compound at the above-described upper limit or less is preferable from the viewpoint of avoiding a problem resulting from the basic compound itself that inhibits etching of the metal layer. Setting the content of the basic compound at the above-described lower limit or greater is preferable from the viewpoint that the Ti layer can be processed at high-speed.

Described about a relation to the oxidizing agent, it is preferable for the basic compound to be used in a range of 10 parts by mass or greater and more preferably 20 parts by mass or greater, with respect to 100 parts by mass of the oxidizing agent. On the other hand, the upper limit thereof is preferably equal to or less than 100 parts by mass and more preferably equal to or less than 70 parts by mass. By using the amounts of the both parties in an appropriate relation, both good etching performance and removability of residue can be realized and high etching selectivity can be achieved in combination therewith.

### (Aqueous Medium)

The etching liquid of the present invention is preferably an aqueous solution in which water is used as a medium and each of components contained therein is uniformly dissolved. The content of water is preferably from 50 to 99.5% by mass and more preferably from 55 to 95% by mass, with respect to the total mass of the etching liquid. Thus, the case where water is a main component (50% by mass or greater) is preferable from the viewpoints that it is more inexpensive and it more adjusts to the environment, compared to the case where proportion of an organic solvent is high. The water may be an aqueous medium containing components dissolved therein in an amount by which the effects of the present invention are not deteriorated, or may contain inevitable microscopic amount of mixed components. Especially, distilled water or an exchanged water, or water which has been subjected to a purifying process, such as ultrapure water is preferable and the ultrapure water which is used for production of the semiconductor is particularly preferable.

(pH)

Usually, as the pH of the etching liquid becomes high, deterioration of the liquid tends to be accelerated. Specifically, when the pH becomes 8.5 or greater, deterioration of the liquid begins to occur. When the pH becomes 9 or greater, deterioration of the liquid is accelerated and when the pH becomes 10 or greater, deterioration of the liquid is more accelerated. However, in the present invention, the pH of the etching liquid is controlled to 8.5 or greater, preferably 9 or greater, more preferably 9.5 or greater, and particularly preferably 10 or greater. As the upper limit, the pH is controlled to be 14 or less, preferably 13.5 or less, and still more preferably 13 or less. By setting the pH to the above-described lower limit or greater, the Ti layer can be removed at a high speed, while by setting the pH to be the above-described upper limit or less, excessive etching of the second layer can be prevented and excessive deterioration of the liquid can be preferably suppressed. The pH refers to a value obtained in accordance with equipment and the conditions used for measurement in Examples, unless otherwise indicated. Further, in a high pH region, usually deterioration of an oxidizing agent (hydrogen peroxide or the like) that is present in such an environment becomes more conspicuous. For example, in the region of pH 8.2 or less that is adopted in the above-described Patent Literature 1, the deterioration of the oxidizing agent becomes very slow. On the other hand, in the range of pH 8.5 (especially 9.5 or greater) defined by the present invention, the deterioration of the oxidizing agent becomes very fast. The definition of the above-described pH range defined in the present invention has a technical significance not only in its relationship with an etching performance, but also its relationship with deactivation due to such deterioration of the oxidizing agent.

### (Other Component)

### pH Controlling Agent

In the present embodiment, the pH of the etching liquid is controlled to be within the above-described range and a pH controlling agent is preferably used for the control thereof. Examples of the pH controlling agent include: in order to increase the pH, a basic compound described in the above-described section of “Basic compound”; in order to decrease the pH, an inorganic acids such as hydrochloric acid, nitric acid, sulfuric acid, and phosphoric acid; and an organic acids such as formic acid, acetic acid, propionic acid, butyric acid, valenic acid, 2-methyl butyric acid, n-hexanoic acid, 3,3-dimethyl butyric acid, 2-ethyl butyric acid, 4-methyl pentanoic acid, n-heptanoic acid, 2-methyl hexanoic acid, n-octanoic acid, 2-ethyl hexanoic acid, benzoic acid, glycolic acid, salicylic acid, gliceric acid, oxalic acid, malonic acid, succinic acid, glutaric acid, adipic acid, pimelic acid, maleic acid, phthalic acid, malic acid, oxalic acid, citric acid, and lactic acid.

The use amount of the pH controlling agent is not particularly limited and an amount necessary to control the pH to the above-described range may be used.

### Water-Soluble Organic Solvent

In the etching liquid used in the present invention, further a water-soluble organic solvent may be added thereto. The water-soluble organic solvent means an organic solvent that can be mixed with water in an arbitrary proportion. This is effective at capability of improving in-plane uniform etching property of the wafer.

Examples of the water-soluble organic solvent include: alcohol compound solvents, such as methyl alcohol, ethyl alcohol, 1-propyl alcohol, 2-propyl alcohol, 2-butanol, ethylene glycol, propylene glycol, glycerol, 1,6-hexanediol, cyclohexanediol, sorbitol, xylitol, 2-methyl-2,4-pentanediol, 1,3-butanediol, and 1,4-butanediol; ether compound solvents, such as an alkylene glycol alkyl ether including ethylene glycol monomethyl ether, ethylene glycol monobuthyl ether, diethylene glycol, dipropylene glycol, propylene glycol monomethyl ether, diethylene glycol monomethyl ether, triethylene glycol, poly(ethylene glycol), dipropylene glycol monomethyl ether, tripropylene glycol monomethyl ether, and diethylene glycol monobutyl ether.

Among these solvents, preferred are alcohol compound solvents having 2 to 15 carbon atoms and ether compound solvents having 2 to 15 carbon atoms (preferably hydroxyl group-containing ether compounds). More preferred are alcohol compound solvents having 2 to 10 carbon atoms and at least 2 hydroxyl groups and ether compound solvents having 2 to 10 carbon atoms and at least 2 hydroxyl groups (preferably hydroxyl group-containing ether compounds). Especially preferred are alkyleneglycol alkylethers having 3 to 8 carbon atoms. The water-soluble organic solvent may be used singly or appropriately in combination of two or more kinds. In the present specification, a compound having a hydroxyl group (—OH) and an ether group (—O—) in the molecule thereof shall be included in the category of the ether compound in principle (not called as the alcohol compound). When a compound having both a hydroxyl group and an ether group is mentioned in particular, the compound may be preferably called as “hydroxyl group-containing ether compound”.

Especially among these compounds, propyleneglycol and dipropyleneglycol are preferable and dipropyleneglycol is more preferable. The addition amount thereof is preferably from 0.1 to 70% by mass and more preferably from 10 to 50% by mass, with respect to the total mass of the etching liquid. By setting the addition amount to the above-described lower limit or greater, improvement in uniformity of the above-described etching can be effectively realized.

In the present invention, addition of the water-soluble organic solvent is very effective. The addition thereof makes its excellent selective etching effect conspicuous whereby a high etching effect can be achieved in a variety of constitutional embodiments.

### Complex Compound

In order to suppress excessive etching of the second layer (for example, a Cu layer), it is preferable that a complex compound such as ethylenediamine tetraacetic acid (EDTA) is not used in the etching liquid according to the present invention. From the above-described viewpoint, it is preferable that the etching liquid of the present invention consists substantially of the above-described basic compound, the oxidizing agent and the water medium, or consists substantially of the above-described basic compound, the oxidizing agent, the water-soluble organic solvent and the water medium. Herein, the term “substantially” means that the etching liquid may contain components such as inevitable impurities to an extent in which the present invention exerts a desirable effect.

### [Kit]

The etching liquid of the present invention may be constituted as a kit in which the raw materials thereof are divided into multiple parts. Examples of the kit include an embodiment in which, as a first liquid, a liquid composition in which the above-described basic compound is contained in a water medium is prepared, and, as a second liquid, a liquid composition in which the above-described oxidizing agent is contained in a water medium is prepared. As an example of the use thereof, preferred is an embodiment in which both liquids are mixed to prepare an etching liquid, and after that, the etching liquid is applied to the above-described etching process on a timely basis. This avoids it from raising deterioration of the liquid properties due to decomposition of the oxidizing agent (for example, hydrogen peroxide) whereby a desired etching function can be effectively exhibited. The formulae or the like of both the first liquid and the second liquid in this kit are the same as those described above.

### [Residue]

The production process of the semiconductor device may include a step of etching a metal layer or the like on a semiconductor substrate by a plasma etching technique using a resist pattern or the like as a mask. Specifically, etching of the metal layer, a semiconductor layer, an insulating layer, and the like is conducted, thereby patterning the metal layer and the semiconductor layer, or forming, on the insulating layer, an opening portion such as a via hale and a wiring groove. In the plasma etching, a residue derived from the resist used as a mask, and the metal layer, the semiconductor layer, and the insulating layer to be etched is formed on the semiconductor substrate. In the present invention, the residue formed by the plasma etching as described above is called as “a plasma etching residue”. The “plasma etching residue” includes an etching residue derived from the above-described second layer (SiON, SiOC, and the like).

Further, the resist pattern used as a mask is removed after etching. In order to remove the resist pattern, as described above, a wet method using a stripper liquid, or a dry method in which ashing is conducted using, for example, plasma or ozone, is used. In the ashing, an altered residue of the plasma etching residue formed by the plasma etching and a residue derived from the resist to be removed are formed on the semiconductor substrate. In the present invention, the residue formed by the ashing as described above is called as an “ashing residue”. Further, as the general term for the residual matter which is formed on the semiconductor substrate and should be removed by washing, such as the plasma etching residue and the ashing residue, they may be simply called as a “residue”.

The plasma etching residue and the ashing residue which are the residue after such etching (Post Etch Residue) are preferably washed and removed using a washing composition. The etching liquid according to the present embodiment can be also used as a washing liquid for removing the plasma etching residue and/or the ashing residue. Especially, the etching liquid is preferably used to remove both the plasma etching residue and the ashing residue after the plasma ashing which is conducted in succession to the plasma etching.

### [Material to be Processed]

A material, which is etched by applying thereto the etching liquid according to the present embodiment, may be arbitrarily used. However, it is required that the material be applied to a semiconductor substrate having a first layer containing Ti. Further, the semiconductor substrate preferably has a second layer containing at least one of Cu, SiO, SiN, SiOC and SiON, and it is preferable that the second layer is not etched by the etching liquid according to the present embodiment. In the present specification, when a metal compound is described by arranging constituting elements in a line, like SiOC, it means SiOₓC_{y} (each of x and y represents an arbitrary composition). However, the compound may be sometimes shown by describing a composition term, like SiOₓ or the like.

### First Layer

A first layer is a layer containing Ti. Especially, a TiN layer is particularly preferable. The thickness of the first layer is not particularly limited. However, when compositions of ordinary devices are considered, it is practical that the thickness is approximately from 0.005 to 0.3 μm. The etching rate [R1] of the first layer is not particularly limited. However, when production efficiency is considered, a high etching rate is preferable and the etching rate is preferably from 50 to 500 angstrom/min.

### Second Layer

A second layer is preferably a layer containing at least one of Cu, SiO, SiN, SiOC and SiON. The thickness of the second layer is not particularly limited. However, when compositions of ordinary devices are considered, it is practical that the thickness is approximately from 0.005 to 0.5 μm. The etching rate [R2] of the second layer is not particularly limited. However, when production efficiency is considered, the etching rate is preferably controlled to a low etching grade and preferably from 0.001 to 10 angstrom/min.

In the selective etching of the first layer, its etching rate ratio ([R1]/[R2]) is not particularly limited. However, when described based on the premise of a device that needs a high selectivity, the etching rate ratio is preferably equal to or greater than 50. In the definition of the range, the etching rate ratio is preferably from 10 to 5,000, more preferably from 30 to 3,000, and particularly preferably from 50 to 2,500.

### [Production of Semiconductor Substrate Product]

In the present embodiment, a semiconductor substrate product having a desired structure is preferably produced through a step of providing a semiconductor substrate by forming the above-described first layer and second layer on a silicon wafer, a step of preparing an etching liquid having the particular formula described above, and a step of applying the etching liquid on the semiconductor substrate thereby dissolving the first layer. At this moment, it is preferable that a second layer is further provided on the semiconductor substrate and the first layer is selectively dissolved with respect to the second layer. It is preferable that prior to the above-described etching step, the semiconductor substrate is subjected to a dry etching or dry ashing step and a residue formed in the step is removed. Further, etching may preferably be conducted using an etching liquid containing nitric acid while protecting Cu. To each of the steps in the production of a semiconductor substrate product, ordinarily each of processing methods that are applied to this kind of product may be applied.

### EXAMPLES

The present invention will be described in more detail based on examples given below, but the invention is not meant to be limited by these.

### Example 1 and Comparative example 1

By applying onto a semiconductor substrate, a first liquid and a second liquid shown in the following Table 1, etching of the substrate was performed (in Table 1, the first liquid is represented by Line-A while the second liquid by Line-B). At this moment, in the Test 111 and the like in which the time after mixing of the two liquids was less than 1 minute, the two liquids were subjected to circulation through Flow channel fa and Flow channel fb and were fed to a processing room after mixing of the two liquids, using equipment shown in FIG. 2. On the other hand, those other than the two liquids were allowed to remain until the specified time after the two liquids were mixed in a bath, and then those were introduced to Flow channel fc, thereby feeding to the processing room. The compositions of the two liquids were adjusted using water so that the percentage by mass of each component in the liquid after mixing thereof was the same as shown in Table 1. The etching liquid was prepared by mixing the first liquid and the second liquid. As typical examples thereof, formulae of Tests 111, 181, 182, 183, and 184 are shown below.

TABLE A

| | Line-A | | Line-B | Mixing |
|---|---|---|---|---|
| No. | DPG (mass %) | TMAH (mass %) | H₂O₂ (mass %) | ratio |
| 111 | 60 | 5.0 | 10 | 1:1 |
| 181 | 60 | 5.0 | 2 | 1:1 |
| 182 | 60 | 5.0 | 6 | 1:1 |
| 183 | 60 | 5.0 | 20 | 1:1 |
| 184 | 60 | 5.0 | 30 | 1:1 |

Each medium of the first liquid and the second liquid was ultrapure water.

The mixing ratio is a mixing proportion (mass standard) of the first liquid and the second liquid [First liquid:Second liquid].

### <Etching Test>

Test wafer: A semiconductor substrate (specimen) was prepared, in which a TiN layer, a SiOC layer and a Cu layer were disposed on a silicon wafer in a state where they were arranged for Test and Evaluation. Using single wafer type cleaning equipment (POLOS (trade name) manufactured by SPS-Europe B.V. Corporation), this specimen was subjected to etching under the following conditions, and evaluation test was conducted.
Discharge rate: 1 L/min.
Wafer rotation number: 500 rpm
Chemical liquid processing temperature: shown in Table 1
Swing speed: shown in Table 1

### [Temperature of Chemical Liquid Processing]

A radiation thermometer IT-550F manufactured by HORIBA, Ltd. was fixed at the height of 30 cm above the wafer in single wafer type equipment. The thermometer was pointed at the wafer surface of 2 cm outside of the wafer center, and temperature measurement was conducted while circulating a chemical liquid. The temperature was measured by digital output from the radiation thermometer and continuously recorded on a personal computer. Among them, an averaged value of the temperature during the period of 10 seconds after stability of the temperature was used as a temperature on the wafer (chemical liquid processing temperature).

### [Measurement of Swing Speed]

In the present example, a movable nozzle, which exhibits a straight movement locus as shown in FIG. 3, was used. The moving speed thereof was determined by altering setup conditions of equipment. The setup values are shown in Table 1.

[Measurement of pH]

The pH shown in the Table is values obtained by measuring an etching liquid which has been prepared by mixing a first liquid and a second liquid, immediately after the preparation (within approximately 2 minutes) at room temperature (25° C.) using F-51 (trade name) manufactured by HORIBA Ltd.

[Elapsed Time after Mixing with Oxidizing Agent]

A time period, from when an etching liquid has been prepared by mixing a first liquid containing a basic compound which is fed from Line-A and a second liquid containing an oxidizing agent which is fed from Line-B till right before applying the etching liquid onto a semiconductor substrate, was defined as an elapsed time after mixing with the oxidizing agent. With respect to those in which the elapsed time was less than 1 minute (Test 111 and the like), the setup conditions therefor were adjusted such that the transit time was estimated to be sufficiently less than 1 minute from the length of Flow channel fc of the apparatus shown in FIG. 2 (length of from the injunction point to the discharge opening) and the flow velocity. With respect to those other than the above, the elapsed time was adjusted by the time to leave it after mixing as described above.

[Water-Washing after Processing]

The case where the semiconductor substrate surface after the etching processing was washed with water (ultrapure water) was indicated as “conducted”, while the case where it was not washed was indicated as “none”.

### [Evaluation of Defect in Performance]

The wafer surface after etching was observed using a Defect Inspection System (trade name SP-1, manufactured by KAL-Tencor Corporation) and evaluation was conducted with respect to the number of TiN residue on the surface. Measurement was conducted on the condition that when a residue having a size of 0.2 μm or greater was present, the defect number was 1.

The defect number in terms of 0.2 μm or greater was:

A: less than 50/12 inch

B: from 50 to less than 200/12 inch

C: 200 or more/12 inch

[Evaluation of in-Plane Uniformity of 12 Inch Wafer]

Condition setting required for the etching depth at the center of a circular substrate (12 inches in diameter) was conducted at different time periods whereby the time period required to be 300 angstrom of the etching depth was confirmed. Then, the entire substrate was again etched at the confirmed time period, and at this moment, the measurement of the obtained etching depth was conducted at the centrally-directed position of 30 mm from the periphery of the substrate. Evaluation was conducted on the condition that as the depth is near 300 angstrom, in-plane uniformity becomes high. Specific criteria are as follows. In this measurement, 10-point measuring positions were set and thus evaluation was performed in terms of average value thereof.

A ±from 10 to less than 50 angstrom

B ±from 50 to less than 100 angstrom

C ±from 100 to less than 150 angstrom

TABLE 1-1

| | | | | | | | Elapsed | |
|---|---|---|---|---|---|---|---|---|
| | Line-A | | Line-B | | Processing | | time | Swing |
| | Basic compound | Organic solvent | Oxidizing agent | | temperature | Water | period | speed |
| TEST | (mass %) | (mass %) | (mass %) | pH | (° C.) | washing | (min) | (cm/s) |
| 111 | TMAH (2.5) | DPG (30) | H₂O₂ (5) | 12.5 | 60 | conducted | <1 | 7 |
| 112 | TMAH (2.5) | DPG (30) | H₂O₂ (5) | 12.5 | 60 | conducted | 3 | 7 |
| 113 | TMAH (2.5) | DPG (30) | H₂O₂ (5) | 12.5 | 60 | conducted | 5 | 7 |
| 114 | TMAH (2.5) | DPG (30) | H₂O₂ (5) | 12.5 | 60 | conducted | 10 | 7 |
| 115 | TMAH (2.5) | DPG (30) | H₂O₂ (5) | 12.5 | 60 | conducted | 30 | 7 |
| C11 | TMAH (2.5) | DPG (30) | H₂O₂ (5) | 12.5 | 60 | conducted | >60 | 7 |
| 121 | TMAH (2.5) | DPG (30) | H₂O₂ (5) | 12.5 | 40 | conducted | <1 | 7 |
| 122 | TMAH (2.5) | DPG (30) | H₂O₂ (5) | 12.5 | 50 | conducted | <1 | 7 |
| 123 | TMAH (2.5) | DPG (30) | H₂O₂ (5) | 12.5 | 60 | conducted | <1 | 7 |
| 124 | TMAH (2.5) | DPG (30) | H₂O₂ (5) | 12.5 | 70 | conducted | <1 | 7 |
| 125 | TMAH (2.5) | DPG (30) | H₂O₂ (5) | 12.5 | 80 | conducted | <1 | 7 |
| 131 | TMAH (2.5) | DPG (30) | H₂O₂ (5) | 12.5 | 60 | conducted | <1 | 1 |
| 132 | TMAH (2.5) | DPG (30) | H₂O₂ (5) | 12.5 | 60 | conducted | <1 | 3 |
| 133 | TMAH (2.5) | DPG (30) | H₂O₂ (5) | 12.5 | 60 | conducted | <1 | 5 |
| 134 | TMAH (2.5) | DPG (30) | H₂O₂ (5) | 12.5 | 60 | conducted | <1 | 15 |
| 141 | TMAH (2.5) | DPG (30) | H₂O₂ (5) | 12.5 | 60 | conducted | <1 | — |
| 151 | TMAH (2.5) | PG (30) | H₂O₂ (5) | 12.3 | 60 | conducted | <1 | 7 |
| 152 | TMAH (2.5) | TPG (30) | H₂O₂ (5) | 12.5 | 60 | conducted | <1 | 7 |
| 153 | TMAH (2.5) | | H₂O₂ (5) | 11.5 | 60 | conducted | <1 | 7 |
| 154 | TMAH (2.5) | DPG (10) | H₂O₂ (5) | 12 | 60 | conducted | <1 | 7 |
| 155 | TMAH (2.5) | DPG (50) | H₂O₂ (5) | 12.8 | 60 | conducted | <1 | 7 |
| 156 | TMAH (2.5) | DPG (80) | H₂O₂ (5) | 13.1 | 60 | conducted | <1 | 7 |

| | | | | | | Selectivity ratio | | |
|---|---|---|---|---|---|---|---|---|
| | | TiN | Cu | Selectivity ratio 1 | SiOC | 2 | Defect in | In-plane uniformity of |
| TEST | Equipment | [Rₘ] | [R_{Cu}] | TiN/Cu | [R_{Si}] | TiN/SiOC | performance | etching |
| 111 | A | 180 | 0.8 | 225 | 0.3 | 600 | A | A |
| 112 | A | 145 | 0.9 | 161 | 0.3 | 483 | A | A |
| 113 | A | 110 | 1.1 | 100 | 0.4 | 275 | A | A |
| 114 | A | 95 | 1.2 | 79 | 0.4 | 238 | A | A |
| 115 | A | 60 | 1.4 | 43 | 0.4 | 150 | A | A |
| C11 | A | 15 | 1.5 | 10 | 0.6 | 25 | B | B |
| 121 | A | 35 | 0.5 | 70 | 0.1 | 350 | A | A |
| 122 | A | 85 | 0.6 | 142 | 0.2 | 425 | A | A |
| 123 | A | 180 | 0.8 | 225 | 0.3 | 600 | A | A |
| 124 | A | 350 | 1.6 | 219 | 0.6 | 583 | A | A |
| 125 | A | 620 | 3.2 | 194 | 1.1 | 564 | A | A |
| 131 | A | 181 | 0.8 | 226 | 0.3 | 603 | A | B |
| 132 | A | 179 | 0.7 | 256 | 0.3 | 597 | A | A |
| 133 | A | 178 | 0.8 | 223 | 0.3 | 593 | A | A |
| 134 | A | 182 | 0.9 | 202 | 0.3 | 607 | A | B |
| 141 | B | 205 | 1.5 | 137 | 0.9 | 228 | B | B |
| 151 | A | 170 | 0.9 | 189 | 0.3 | 567 | B | A |
| 152 | A | 173 | 0.8 | 216 | 0.3 | 577 | B | A |
| 153 | A | 145 | 1.2 | 121 | 0.6 | 242 | B | B |
| 154 | A | 165 | 0.8 | 206 | 0.4 | 413 | A | A |
| 155 | A | 200 | 0.5 | 400 | 0.3 | 667 | A | A |
| 156 | A | 180 | 0.6 | 300 | 0.5 | 360 | A | A |

TABLE 1-2

| | Line-A | | Line-B | | | | Elapsed | |
|---|---|---|---|---|---|---|---|---|
| | Basic | Organic | Oxidizing | | Processing | | time | Swing |
| | compound | solvent | agent | | temperature | Water | period | speed |
| TEST | (mass %) | (mass %) | (mass %) | pH | (° C.) | washing | (min) | (cm/s) |
| 161 | TEAH (2.5) | DPG (30) | H₂O₂ (5) | 12.1 | 60 | conducted | <1 | 7 |
| 162 | TBAH (2.5) | DPG (30) | H₂O₂ (5) | 12 | 60 | conducted | <1 | 7 |
| 163 | Choline (2.5) | DPG (30) | H₂O₂ (5) | 12 | 60 | conducted | <1 | 7 |
| 164 | DEA (2.5) | DPG (30) | H₂O₂ (5) | 11.5 | 60 | conducted | <1 | 7 |
| 165 | DPA (2.5) | DPG (30) | H₂O₂ (5) | 12.5 | 60 | conducted | <1 | 7 |
| 171 | TMAH (0.5) | DPG (30) | H₂O₂ (5) | 12 | 60 | conducted | <1 | 7 |
| 172 | TMAH (1.0) | DPG (30) | H₂O₂ (5) | 12.2 | 60 | conducted | <1 | 7 |
| 173 | TMAH (5.0) | DPG (30) | H₂O₂ (5) | 12.8 | 60 | conducted | <1 | 7 |
| 174 | TMAH (10.0) | DPG (30) | H₂O₂ (5) | 13.5 | 60 | conducted | <1 | 7 |
| 181 | TMAH (2.5) | DPG (30) | H₂O₂ (1) | 12.8 | 60 | conducted | <1 | 7 |
| 182 | TMAH (2.5) | DPG (30) | H₂O₂ (3) | 12.6 | 60 | conducted | <1 | 7 |
| 183 | TMAH (2.5) | DPG (30) | H₂O₂ (10) | 12 | 60 | conducted | <1 | 7 |
| 184 | TMAH (2.5) | DPG (30) | H₂O₂ (15) | 11 | 60 | conducted | <1 | 7 |
| C12 | | DPG (30) | H₂O₂ (5) | 6.8 | 60 | conducted | <1 | 7 |
| C13 | TMAH (2.5) | DPG (30) | | 14 | 60 | conducted | <1 | 7 |

| | | | | Selectivity | | Selectivity | | |
|---|---|---|---|---|---|---|---|---|
| | | TiN | Cu | ratio 1 | SiOC | ratio 2 | Defect in | In-plane uniformity |
| TEST | Equipment | [Rₘ] | [R_{Si}] | TiN/Cu | [R_{Si}] | TiN/SiOC | performance | of etching |
| 161 | A | 165 | 0.9 | 183 | 0.4 | 413 | A | B |
| 162 | A | 160 | 0.9 | 178 | 0.5 | 320 | A | B |
| 163 | A | 142 | 1.1 | 129 | 0.3 | 473 | A | B |
| 164 | A | 150 | 1 | 150 | 0.3 | 500 | A | B |
| 165 | A | 154 | 1 | 154 | 0.3 | 513 | A | B |
| 171 | A | 163 | 0.8 | 204 | 0.4 | 408 | A | A |
| 172 | A | 168 | 0.8 | 210 | 0.4 | 420 | A | A |
| 173 | A | 195 | 0.6 | 325 | 0.6 | 325 | A | A |
| 174 | A | 210 | 0.4 | 525 | 0.9 | 233 | A | B |
| 181 | A | 145 | 0.6 | 242 | 0.5 | 290 | A | B |
| 182 | A | 165 | 0.7 | 236 | 0.4 | 413 | A | A |
| 183 | A | 175 | 0.8 | 219 | 0.3 | 583 | A | A |
| 184 | A | 165 | 1.5 | 110 | 0.2 | 825 | B | A |
| C12 | A | 0.5 | 3.5 | 0 | 0.3 | 2 | — | — |
| C13 | A | 7 | 0.2 | 35 | 2.7 | 3 | — | — |

### (Notes in Table 1)

TiN[Rₘ]: each of etching rates (angstrom/min) with respect to a TiN layer
Cu[R_{Cu}]: each of etching rates (angstrom/min) with respect to a Cu layer
SiOC[R_{Si}]: each of etching rates (angstrom/min) with respect to a SiOC layer
Selectivity ratio 1 (TiN/Cu): etching rate ratio of TiN with respect to Cu
Selectivity ratio 2 (TiN/SiOC): etching rate ratio of TiN with respect to SiOC

TMAH: tetramethylammonium hydroxide

TEAH: tetraethylammonium hydroxide

TBAH: tetrabuthylammonium hydroxide

Choline: represented bellow:

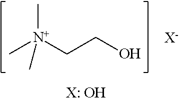

DEA: diethylamine

DPA: dipropylamine

DPG: dipropylene glycol

PG: propylene glycol

TPG: tripropylene glycol

Each medium of the first liquid and the second liquid was ultrapure water.

Equipment used: A: single wafer type equipment, B: batch equipment
Test No.: those that begin with C are Comparative Examples.
Bold face: they indicate items that should be referenced as being a change of the test level.
“-”: this indicates that each of C12 and C13 was too slow in etching speed to perform evaluation.

As shown in Table 1, Comparative Example (Test C11) had a reduced activity of the etching liquid and, therefore, it was not capable of selective etching of TiN and suppression of etching unevenness. In contrast, each of etching liquids of Examples (Tests 111 to 115) exhibited high etching speed with respect to TiN, while each of them exhibited high selectivity of etching such that each of them caused no damage to both SiOC and Cu. Further, the etching unevenness could be favorably suppressed. As a result, it is seen that not only production quality of the semiconductor substrate having a specific structure, but also production efficiency (productivity) can be substantially improved. Further, it is seen that the effects can be achieved under the wide range of conditions including other embodiments having diversified modifications (Tests 121 to 184).

### Example 2

Test 201 was designated as a control which had the same conditions as Test 111. After the etching processing in accordance with Test 201 for the period of given time, the etching liquid after processing was recovered and a continuous processing was performed by adding thereto hydrogen peroxide so that an accumulated amount of the hydrogen peroxide was 10% by mass (Test 202), 15% by mass (Test 203), or 20% by mass (Test 204) in series (see Step V in FIG. 1). The results thereof are shown in Table 2.

TABLE 2

| | Line-A | | Line-B | | | | | | |
|---|---|---|---|---|---|---|---|---|---|
| | Basic | Organic | Oxidizing | | Processing | Elapsed time period after mixing | | | |
| | compound | solvent | agent | | temperature | (min) | | | |
| TEST | (mass %) | (mass %) | (mass %) | pH | (° C.) | 1^{st}-time | 2^{nd}-time | 3^{rd}-time | 4^{th}-time |
| 201 | TMAH (2.5) | DPG (30) | H₂O₂ (5) | 12.5 | 60 | <1 | | | |
| 202 | TMAH (2.5) | DPG (30) | H₂O₂ (10) | 11.8 | 60 | | <1 | | |
| 203 | TMAH (2.5) | DPG (30) | H₂O₂ (15) | 11 | 60 | | | <1 | |
| 204 | TMAH (2.5) | DPG (30) | H₂O₂ (20) | 10 | 60 | | | | <1 |

| | | | Selectivity ratio | | | | In-plane |
|---|---|---|---|---|---|---|---|
| | | | 1 | | Selectivity ratio 2 | Defect in | uniformity |
| TEST | TiN [Rₘ] | Cu [R_{Cu}] | TiN/Cu | SiOC [R_{Si}] | TiN/SiOC | performance | of etching |
| 201 | 180 | 0.8 | 225 | 0.3 | 600 | A | A |
| 202 | 172 | 1 | 172 | 0.2 | 860 | A | A |
| 203 | 165 | 1.2 | 138 | 0.2 | 825 | A | A |
| 204 | 150 | 2 | 75 | 0.1 | 1,500 | B | A |

### (Notes in Table 2)

In each of Tests 201 to 204, single wafer type equipment was used. The etching conditions thereof were set in the same manner as Example 1. The swing speed was set to 7 cm/s. In each Test, washing with water (ultrapure water) after the etching processing was conducted.

As shown in Table 2, it was confirmed that according to the present invention, even after an etching liquid has been used, when the etching liquid is re-prepared by adding thereto hydrogen peroxide, the re-prepared etching liquid sufficiently acts as an etching liquid whereby the re-prepared etching liquid can be repeatedly used.

Having described our invention as related to the present embodiments, it is our intention that the invention not be limited by any of the details of the description, unless otherwise specified, but rather be construed broadly within its spirit and scope as set out in the accompanying claims.

### REFERENCE SIGNS LIST

1 TiN layer
2 SiON layer
3 SiOC layer
4 Cu layer
5 Via
10 Substrate at a state before a TiN film is removed
11 Processing room (tank)
12 Rotary table
13 Discharge opening
14 Junction point
20 Substrate at a state after a TiN film has been removed
A First liquid
B Second liquid
M Rotary drive member
S Semiconductor substrate
t Movement locus of discharge opening
r Rotation direction of substrate

1. A method of etching a semiconductor substrate, comprising the steps of:
preparing an etching liquid by mixing a first liquid with a second liquid to be in the range of pH from 8.5 to 14, the first liquid containing a basic compound, the second liquid containing an oxidizing agent; and then
applying the etching liquid to a semiconductor substrate on a timely basis for etching a Ti-containing layer in or on the semiconductor substrate.

2. The etching method according to claim 1,
wherein the first liquid and the second liquid are, respectively, put into flow channels different from each other, the both liquids are then joined at the injunction portion of the flow channels to mix them, and the etching liquid prepared by the mixing is applied to the semiconductor substrate.

3. The etching method according to claim 1,
wherein the first liquid is an aqueous composition of the basic compound having a concentration from 0.1 to 10% by mass and the second liquid is an aqueous composition of the oxidizing agent having a concentration from 1 to 40% by mass.

4. The etching method according to claim 1,
wherein the etching liquid is prepared so that the concentration of the basic compound in the etching liquid is from 0.05 to 10% by mass.

5. The etching method according to claim 1,
wherein the etching liquid is prepared so that the concentration of the oxidizing agent in the etching liquid is from 0.5 to 10% by mass.

6. The etching method according to claim 1,
wherein the etching liquid is applied to a surface of a rotating semiconductor substrate.

7. The etching method according to claim 1,
wherein the etching liquid is provided from a discharge opening, and
wherein the application of the etching liquid is performed while moving the discharge opening along with a locus headed in the direction from a central portion of the semiconductor substrate to the edge thereof with respect to the surface of the rotating semiconductor substrate.

8. The etching method according to claim 1,
wherein the basic compound is a compound represented by formula (I):
N(R)₄OH Formula (I)
wherein R represents a substituent; and a plurality of Rs may be the same or different from each other.

9. The etching method according to claim 1,
wherein the basic compound is tetramethylammonium hydroxide, tetraethylammonium hydroxide, or tetrapropylammonium hydroxide.

10. The etching method according to claim 1,
wherein the oxidizing agent is hydrogen peroxide, ammonium persulfate, perboric acid, peracetic acid, periodic acid, perchloric acid, or a combination thereof.

11. The etching method according to claim 1,
wherein the temperature, at which the etching liquid is brought into contact with the semiconductor substrate and etches the same, is 40° C. or more.

12. The etching method according to claim 1,
wherein the semiconductor substrate comprises:
a Ti-containing layer as a first layer; and
a second layer containing at least one of Cu, SiO, SiN, SiOC, and SiON,
wherein the first layer is selectively etched with respect to the second layer by the etching.

13. The etching method according claim 12, wherein the first layer is laminated on or above the second layer.

14. The etching method according to claim 12, wherein an etching rate ratio of an etching rate (R1) of the first layer to an etching rate (R2) of the second layer (R1/R2) is 30 or more.

15. The etching method according to claim 12, wherein the etching is conducted after the second layer is processed by a dry etching process.

16. The etching method according to claim 1, wherein the etching liquid comprises a water-soluble organic solvent.

17. The etching method according to claim 16, wherein the water-soluble organic solvent is an alcohol compound or an ether compound.

18. The etching method according to claim 16, wherein the concentration of the water-soluble organic solvent is set at 1 to 50 mass %, with respect to the etching liquid.

19. The etching method according to claim 1, comprising a step of washing with water a substrate surface after etching.

20. A method of producing a semiconductor substrate product, producing the semiconductor substrate product using a semiconductor substrate processed by the etching method according to claim 1.

21. A method of producing a semiconductor device, producing the semiconductor device using the semiconductor substrate product obtained by the production method according to claim 20.

22. A kit for preparation of an etching liquid, comprising:
a first liquid and a second liquid in combination, the first liquid containing a basic compound, the second liquid containing an oxidizing agent,
wherein the etching liquid can be prepared by mixing at least the first liquid with the second liquid, and the etching liquid is on a timely basis to be applied to a semiconductor substrate for etching a Ti-containing layer provided in or on the substrate.
